(19) United States
(12) Patent Application Publication
(10) Pub. No.: US 2008/0216895 A1
(43) Pub. Date: Sep. 11, 2008

(54) Chalcopyrite solar cell and method of manufacturing the same

(75) Inventors: Satoshi Aoki, Tochigi (JP); Hiroyuki Gotou, Tochigi (JP)

Correspondence Address: ARENT FOX LLP, 1050 CONNECTICUT AVENUE, N.W., SUITE 400, WASHINGTON, DC, 20036, US

(73) Assignee: HONDA MOTOR CO., LTD.

(21) Appl. No.: 11/802,312

(22) Filed: May 22, 2007

(30) Foreign Application Priority Data
May 25, 2006 (JP) P. 2006-145487
May 25, 2006 (JP) P. 2006-145600
May 25, 2006 (JP) P. 2006-145742

(51) Int. Cl. H01L 31/032; H01L 31/0264; H01L 31/18

(52) U.S. Cl. 136/265; 438/95; 257/E31.004; 257/E31.027

(57) ABSTRACT

A single unit cell (herein, referred to as “a unit cell”) is formed out of a lower electrode layer (Mo electrode layer) 2 formed on a substrate 1, a light-absorbing layer (CIGS LIGHT-ABSORBING LAYER) 3 including copper, indium, gallium, and selenium, a high-resistance buffer layer thin film 4 formed of InS, ZnS, CdS, and the like on the light-absorbing layer thin film, and an upper electrode thin film (TCO) 5 formed of ZnOAl and the like. In order to connect the unit cell, a part of a contact electrode 6 connecting the upper electrode and the lower electrode is formed to overlap with a dividing line of the lower electrode 2 formed by a first scribing.

### BACKGROUND OF THE INVENTION

The present invention relates to a chalcopyrite solar cell which is a compound-based solar cell, and more particularly, to a chalcopyrite solar cell and a method of manufacturing the same in which a monolithic series connection structure is formed with a small dead space.

A solar cell which receives light and converts the light into electric energy is classified into a bulk system and a thin film system depending on a thickness of a semiconductor.

The thin film system is a solar cell having a thickness of a semiconductor layer smaller than the range of several 10 μm to several μm, and is classified into an Si thin film system and a compound thin film system. The compound thin film system includes a group II-VI compound group, a chalcopyrite group, and the like. Several kinds of the compound thin film systems are commercialized.

The chalcopyrite solar cell included in the chalcopyrite solar system among them is call as a CIGS (CU(InGa)Se) system thin film solar cell, a CIGS solar cell, or a group I-III-VI system on the basis of used substances.

The chalcopyrite solar cell is formed of a chalcopyrite compound as a light-absorbing layer and has characteristics such as high efficiency, no light-deterioration (variation with the elapse of a year), excellent radiation resistance, a wide light-absorbing wavelength area, high light-absorbing coefficient. In recent, the study for mass production is performed.

A sectional structure of a general chalcopyrite solar cell is shown in FIG. 1. As shown in FIG. 1, the chalcopyrite solar cell includes a lower electrode layer (Mo electrode layer) formed on a substrate of a glass and the like, a light-absorbing layer (CIGS light-absorbing layer) containing copper, indium, gallium, and selenium, a buffer layer thin film with high resistance formed of InS, ZnS, CdS, and the like, and an upper electrode thin film (TCO) formed of ZnOAl and the like.

In case of using a soda-lime glass and the like, in order to control a leaching rate of an alkali metal component from the inside of the substrate to the light-absorbing layer, an alkali control layer with an SiO₂ base may be provided.

When light such as sunlight is radiated to the chalcopyrite solar cell, pairs of electrons (−) and holes (+) are generated. The electrons (−) are collected to n-type and the holes (+) are collected to p-type in the contact surface with a semiconductor, whereby an electromotive force is generated between the n-type and the p-type. In this state, when a conductive line is connected to the electrode, current can be taken out.

Steps of manufacturing the chalcopyrite solar cell are described with reference to FIG. 2. First, a Mo (molybdenum) electrode as the lower electrode of the soda-lime glass substrate is formed into a film by sputtering. Next, the Mo electrode is removed and divided by radiating a laser beam (first scribing, FIG. 2A).

After the first scribing, cut chips are cleaned by water and the like, and then copper (Cu), indium (In), and gallium (Ga) are attached thereto by sputtering or deposition to form a layer called as a precursor.

The precursor is input to a forge and is annealed in atmosphere of H₂Se gas at 400° C. to 600° C., whereby a p-type light-absorbing layer is obtained. The annealing process is generally called as gaseous selenide or simply selenide.

Next, an n-type buffer layer such as CdS, ZnO, and InS is laminated on the light-absorbing layer. The buffer layer is formed generally by a dry process such as sputtering or a wet process such as CBD (chemical bath deposition).

Next, the buffer layer and the precursor are removed and divided by radiating a laser beam or by a metal needle (second scribing, FIG. 2B).

Then, a transparent electrode (TCO: Transparent Conducting Oxides) film such as ZnOAl is formed as the upper electrode by sputtering and the like (FIG. 2C).

Finally, the TCO, the buffer layer, and the precursor are removed and divided by radiating a laser beam or by a metal needle and the like (third scribing, FIG. 2D), whereby CIGS film solar cell is obtained.

The obtained solar cell is a thing called as a cell in which a unit cell including the divided lower electrode, the divided light-absorbing layer, and the divided upper electrode is connected to a monolithic in series through the contact electrode. However, a single cell or a plurality of cells is packaged and then is processed as a module (panel).

In the cell, an element division is performed by each scribing process, whereby the plurality of series columns are divided into a monolithic. However, the number of series columns (the number of unit cell) is modified, whereby voltage of the cell can be optionally designed and modified. This is one of merits of the thin film solar cell.

In the conventional chalcopyrite solar cell as described above, the mechanical scribing and the laser beam scribing are used as an art of the second scribing.

The mechanical scribing is an art in which the scribing is mechanically performed by pressing down and moving a metal needle, a front end of which has a taper shape, at a predetermined pressure (for example, refer to Patent Document 1).

FIG. 3 is a schematic diagram illustrating that the second scribing is performed by the mechanical scribing.

In the laser beam scribing, Nd:YAG crystal is excited by a constant discharging lamp such as an arc lamp and then the generated a laser beam (Nd:YAG) is radiated to the light-absorbing layer, whereby the light-absorbing layer is removed and divided (for example, refer to Patent Document 2).

[Patent Document 1]

Japanese Unexamined Patent Application Publication No. 2004-115356

[Patent Document 2]

Japanese Unexamined Patent Application Publication No. 11-312815

In the conventional second scribing as described in Patent Documents 1 or 2, a first, second, and third scribing should be separated in some distance. This reason is described with reference to FIG. 4. FIG. 4A is a sectional view illustrating a structure of a unit cell of the conventional solar cell. As shown in FIG. 4, in conventional, the first scribing, the second scribing, and the third scribing (element division scribing) is performed to be separated each other and the separated parts become dead spaces 8, 9.

In the dead space parts, since the upper electrode and the lower electrode are electrically connected to each other, electrons (−) and holes (+) cannot be accumulated in a boundary surface of n-type semiconductor and p-type semiconductor.

Accordingly, it is required to secure a width of the dead space in the range of 70 μm to 100 μm. The dead space does not contribute to generating electricity and depends on the number of designed series column. However, in the general chalcopyrite solar cell, the dead space 8 between the first scribing and the second scribing is in the range of 2 to 5% in total.

As shown in FIG. 4B, when a part of the second scribing overlaps with the first scribing so as to remove the dead space, cracks occur in the light-absorbing layer and result in leak current. Consequently, generation efficiency (conversion efficiency) decreases.

According to studies of the inventors, when the chalcopyrite solar cell is formed by using the laser beam scribing in the first scribing, using the mechanical scribing in the second scribing, and performing a scribing process so that the second scribing overlaps with a part of the first scribing, the conversion efficiency is averagely about 9.5%.

A chalcopyrite solar cell manufactured by the same process other than the scribing process had conversion efficiency of about 10% in spite of a large dead space. In order to find this reason, the chalcopyrite solar cell designed so that the second scribing overlaps with a part of the first scribing is analyzed. As the result, since a shunt resistance is low and a leak occurs therein, it is confirmed that a FF (fill factor) value becomes lower.

In the conventional scribing art, it is necessary to separate the first scribing and the second scribing in some extent for insulating each unit cell. Since it is difficult to reduce the dead space, it is difficult to improve the conversion efficiency.

Meanwhile, in the chalcopyrite solar cell manufactured by securing the dead spaces of 80 μm between the first, second, and third scribing, the conversion efficiency thereof is about 10% in spite of the dead spaces.

In order to find this reason, the chalcopyrite solar cell designed so that the second scribing overlaps with a part of the first scribing is analyzed. As the result, since a shunt resistance is low and a leak occurs therein, it is confirmed that a FF (fill factor) value becomes lower.

As shown in FIG. 14, when a part of the third scribing overlaps with the second scribing so as to remove the dead space between the second scribing and the third scribing, a contact portion between the transparent electrode layer and the lower electrode (Mo electrode) is peeled off, cracks occurs in a thin part of the transparent electrode, or existing cracks is widened. Accordingly, series resistance increases due to the peeling or the cracks. Consequently, generation efficiency (conversion efficiency) extremely decreases.

According to studies of the inventors, when the chalcopyrite solar cell is formed by using the mechanical scribing in the second scribing, using the same mechanical scribing in the third scribing, and performing a scribing process so that the third scribing overlaps with a part of the second scribing, the conversion efficiency averagely is averagely about 9.5%.

As shown in FIG. 14, when a part of the third scribing overlaps with the second scribing so as to remove the dead space, a contact portion between the upper electrode (transparent electrode layer) and the lower electrode (Mo electrode) is peeled off, cracks occur in a thin part of the upper electrode, or existing cracks are widened. Accordingly, series resistance increases due to the peeling or the cracks. Consequently, generation efficiency (photoelectric conversion efficiency) extremely decreases.

According to studies of the inventors, when the chalcopyrite solar cell is formed by using the mechanical scribing in the second scribing, using the same mechanical scribing in the third scribing, and performing a scribing process so that the third scribing overlaps with a part of the second scribing, the conversion efficiency is averagely about 9.5%.

Meanwhile, when the dead space of 80 μm between the second scribing and the third scribing is formed to manufacture a chalcopyrite solar cell, the conversion efficiency thereof is about 10% in spite of the dead spaces.

In the conventional scribing art, it is necessary to separate the second scribing and the third scribing in some extent for electrically connecting the upper electrode and the lower electrode each other. Since it is difficult to reduce the dead space, it is difficult to improve the conversion efficiency.

### SUMMARY OF THE INVENTION

An object of the invention is to remove the dead space 8 of the dead space 8 generated by separating the first scribing in degree and the second scribing and the dead space 9 generated by separating the second scribing and the third scribing (element division scribing) in degree in the conventional solar cell.

In order to solve the above-mentioned problem, a chalcopyrite solar cell according to the invention includes a substrate, a plurality of lower electrodes formed by dividing a conductive layer formed on the substrate, a chalcopyrite light-absorbing layer formed on the plurality of lower electrodes and divided into a plurality of parts, a contact electrode which is formed between the adjacent lower electrodes and on one of the adjacent lower electrodes and which has a conductivity higher than that of the light-absorbing layer by reforming a part of the light-absorbing layer, an upper electrode which is a transparent conductive layer divided into a plurality of parts at a portion adjacent to the contact electrode, and a dead space continuously remaining in an element division groove of the contact electrode.

The contact electrode may have a Cu/In ratio thereof higher than a Cu/In ratio of the light-absorbing layer, whereby the conductivity increase. The contact electrode may be formed of an alloy containing molybdenum. The upper electrode may be formed on the light-absorbing layer with a buffer layer interposed therebetween.

A method of manufacturing a chalcopyrite solar cell according to the invention includes a conductive layer forming step of forming a conductive layer which becomes a lower electrode on a substrate, a first scribing step of dividing the conductive layer into a plurality of lower electrodes, a light-absorbing layer forming step of forming a light-absorbing layer on the surfaces of the plurality of lower electrodes and the surface of the substrate therebetween, a contact electrode forming step of radiating a laser beam between the adjacent lower electrodes of the light-absorbing layer and onto one of the adjacent lower electrodes so as not to overlap with a part to which an element division scribing is performed later and reforming the light-absorbing layer so that a conductivity of the radiated part of the light-absorbing layer is higher than a conductivity of the non-radiated part thereof, a transparent electrode forming step of laminating a transparent electrode layer, and an element division scribing step of dividing the transparent electrode so as to include the part reformed in the contact electrode forming step.

When the transparent electrode layer which becomes the upper electrode is laminated on the light-absorbing layer with a buffer layer interposed therebetween, a laser beam may be radiated from the upside of the buffer layer so as to include a part divided in the first scribing step.

Further, a chalcopyrite solar cell according to the invention includes a substrate, a plurality of lower electrodes formed by dividing a conductive layer formed on the substrate, a chalcopyrite light-absorbing layer formed on the plurality of lower electrodes and divided into a plurality of parts, a contact electrode which is formed between the adjacent lower electrodes and on one of the adjacent lower electrodes and which has a conductivity higher than that of the light-absorbing layer by reforming a part of the light-absorbing layer, and an upper electrode which is a transparent conductive layer divided into a plurality of parts at a portion adjacent to the contact electrode.

Further, a method of manufacturing a chalcopyrite solar cell according to the invention includes a conductive layer forming step of forming a conductive layer which becomes a lower electrode on a substrate, a first scribing step of dividing the conductive layer into a plurality of lower electrodes, a light-absorbing layer forming step of forming a light-absorbing layer on the surfaces of the plurality of lower electrodes and the surface of the substrate therebetween, a contact electrode forming step of radiating a laser beam between the adjacent lower electrodes of the light-absorbing layer and onto one of the adjacent lower electrodes and reforming the light-absorbing layer so that a conductivity of the radiated part of the light-absorbing layer is higher than a conductivity of the non-radiated part thereof, a transparent electrode forming step of laminating a transparent electrode layer, and an element division scribing step of dividing the transparent electrode so as to include the part reformed in the contact electrode forming step.

Further, a chalcopyrite solar cell according to the invention includes a substrate, a plurality of lower electrodes formed by dividing a conductive layer formed on the substrate, a chalcopyrite light-absorbing layer formed on the plurality of lower electrodes and divided into a plurality of parts, a contact electrode which is formed on one lower electrode separated from the space between the adjacent lower electrodes and which has a conductivity higher than that of the light-absorbing layer by reforming a part of the light-absorbing layer, and an upper electrode which is a transparent conductive layer divided into a plurality of parts at a portion adjacent to the contact electrode.

A method of manufacturing a chalcopyrite solar cell according to the invention includes a conductive layer forming step of forming a conductive layer which becomes a lower electrode on a substrate, a first scribing step of dividing the conductive layer into a plurality of lower electrodes, a light-absorbing layer forming step of forming a light-absorbing layer on the surfaces of the plurality of lower electrodes and the surface of the substrate therebetween, a contact electrode forming step of radiating a laser beam onto a part of the light-absorbing layer formed on one lower electrode separated from the space between the adjacent lower electrodes and reforming the light-absorbing layer so that a conductivity of the radiated part of the light-absorbing layer is higher than a conductivity of the non-radiated part thereof, a transparent electrode forming step of laminating a transparent electrode layer, and an element division scribing step of dividing the transparent electrode so as to include the part reformed in the contact electrode forming step.

In the invention, a contact electrode in which a light-absorbing layer is reformed so as to increase a conductive rate thereof is formed so that a part of the contact electrode overlaps with an area where a first scribing is performed. A third scribing is performed in a part adjacent to the contact electrode, whereby an upper electrode of one unit cell of the adjacent unit cells is electrically connected to a lower electrode of the other unit cell. Then, a dead space can be reduced while a leak current does not occur. Accordingly, a chalcopyrite solar cell having high photoelectric conversion efficiency can be obtained.

Further, in the invention, a contact electrode in which the light-absorbing layer is reformed to increase a conductive rate thereof is formed as replaced for a second scribing. A third scribing as an element division scribing is performed so that a part thereof overlaps with the contact electrode portion, whereby a dead space is reduced after securing a connection between a transparent electrode layer and an lower electrode layer. Accordingly, a chalcopyrite solar cell having high photoelectric conversion efficiency can be obtained.

### BRIEF DESCRIPTION OF THE DRAWINGS

FIG. 1 is a sectional view illustrating a structure of a conventional chalcopyrite solar cell.

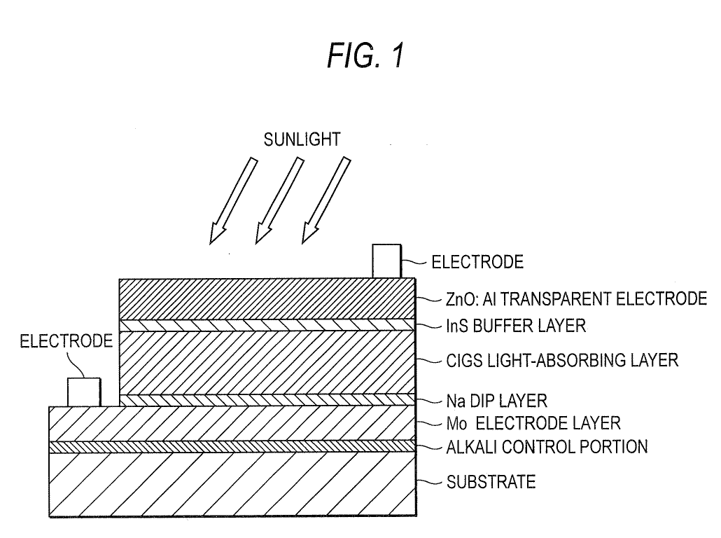

FIGS. 2A to 2D are diagrams illustrating a process of manufacturing a conventional chalcopyrite solar cell.

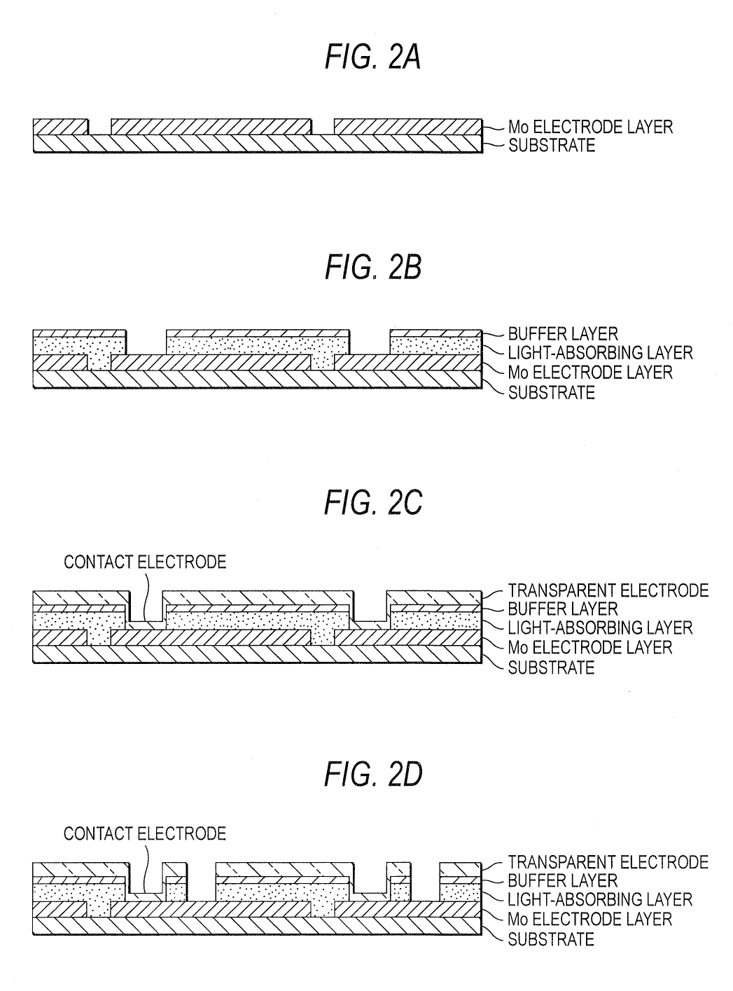

FIG. 3 is a diagram illustrating a scribing form by a metal needle.

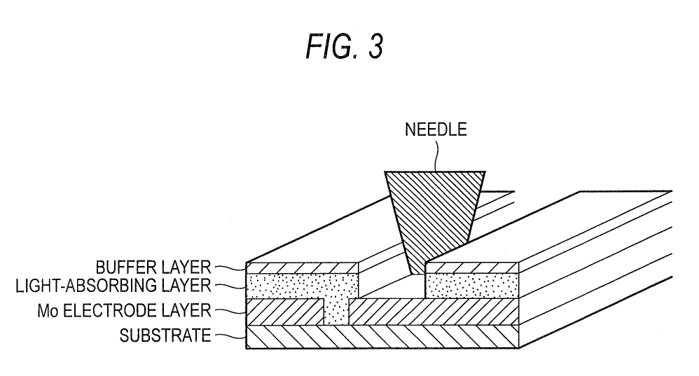

FIGS. 4A and 4B are sectional views of a conventional chalcopyrite solar cell.

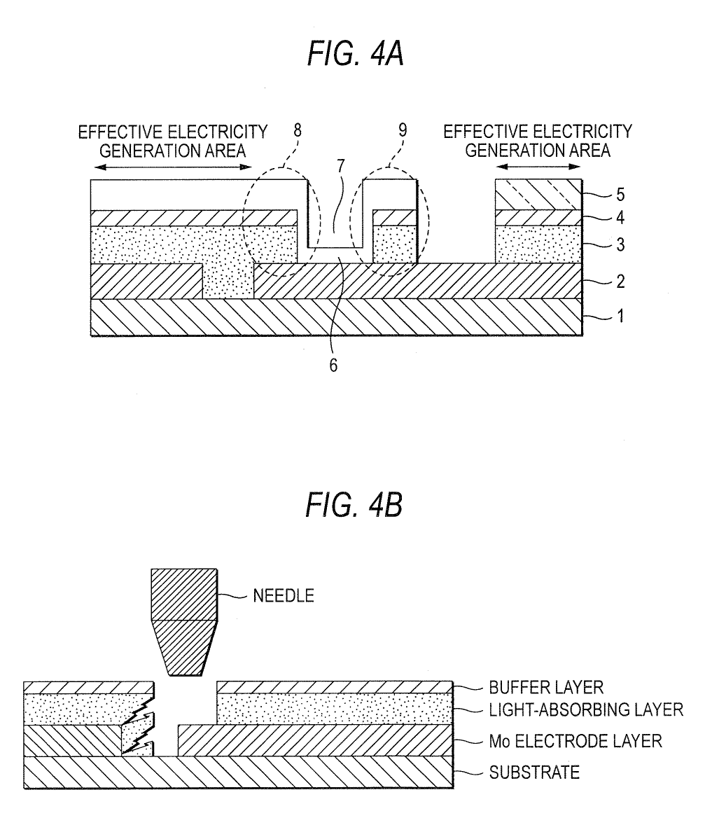

FIG. 5 is a sectional view of a chalcopyrite solar cell according to the invention.

FIG. 6 is a diagram illustrating a method of manufacturing a chalcopyrite solar cell of the invention.

FIG. 7 is a picture of a surface of a solar cell in which a contact electrode is formed by a laser contact forming process of the invention.

FIG. 8A is a graph illustrating a component analysis result of a light-absorbing layer in which a laser-light contact forming process is not performed and FIG. 8B is a graph illustrating a component analysis result of a laser-light contact portion in which a light-laser contact forming process is performed.

FIG. 9A is a graph illustrating a difference in carrier density of a light-absorbing layer due to a Cu/In ratio and FIG. 9B is a graph illustrating a variation in resistance ratio due to a Cu/In ratio.

FIG. 10 is a microscope picture taking a surface of a chalcopyrite solar cell after lamination of a transparent electrode (TCO).

FIG. 11 is a sectional SEM picture of a contact electrode and a light-absorbing layer.

FIG. 12 is a sectional view of a chalcopyrite solar cell according to the invention.

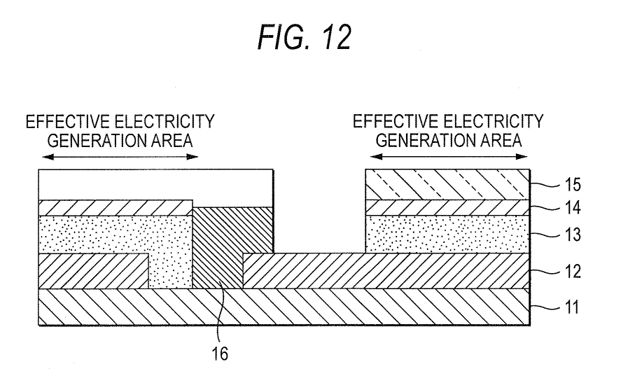

FIG. 13 is a diagram illustrating a method of manufacturing a chalcopyrite solar cell of the invention.

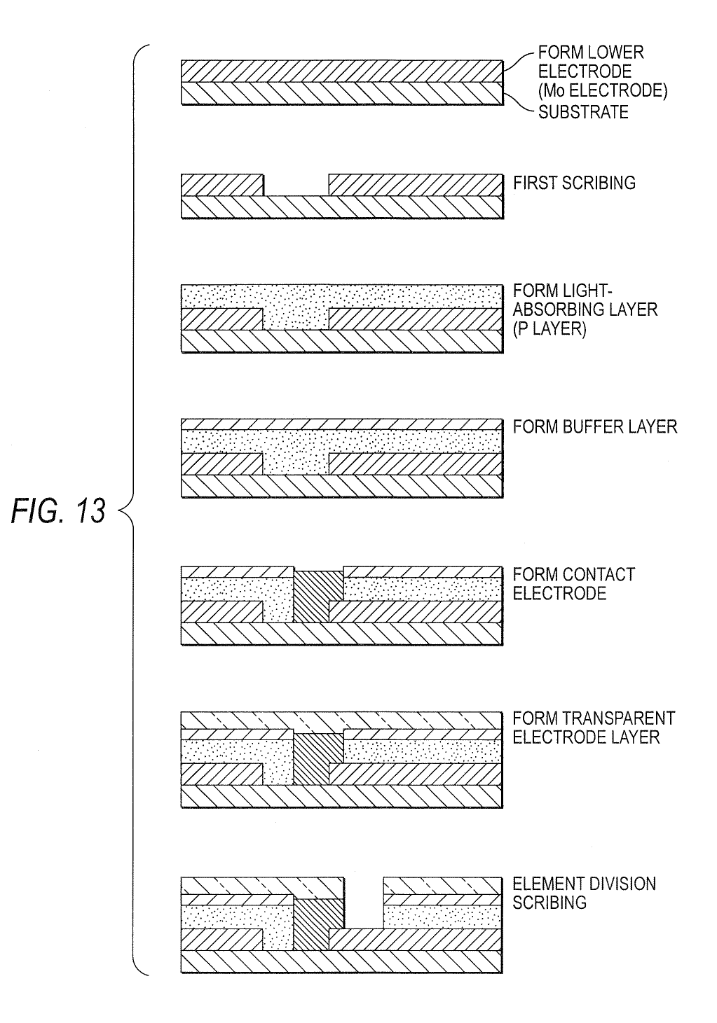

FIG. 14 is a sectional view of a conventional chalcopyrite solar cell.

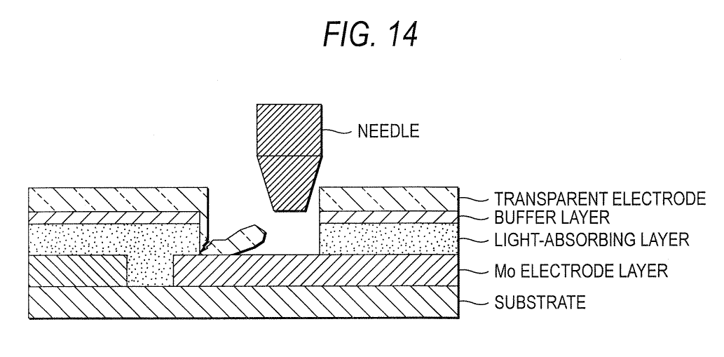

FIG. 15 is a sectional view of a chalcopyrite solar cell according to the invention.

FIG. 16 is a diagram illustrating a method of manufacturing a chalcopyrite solar cell of the invention.

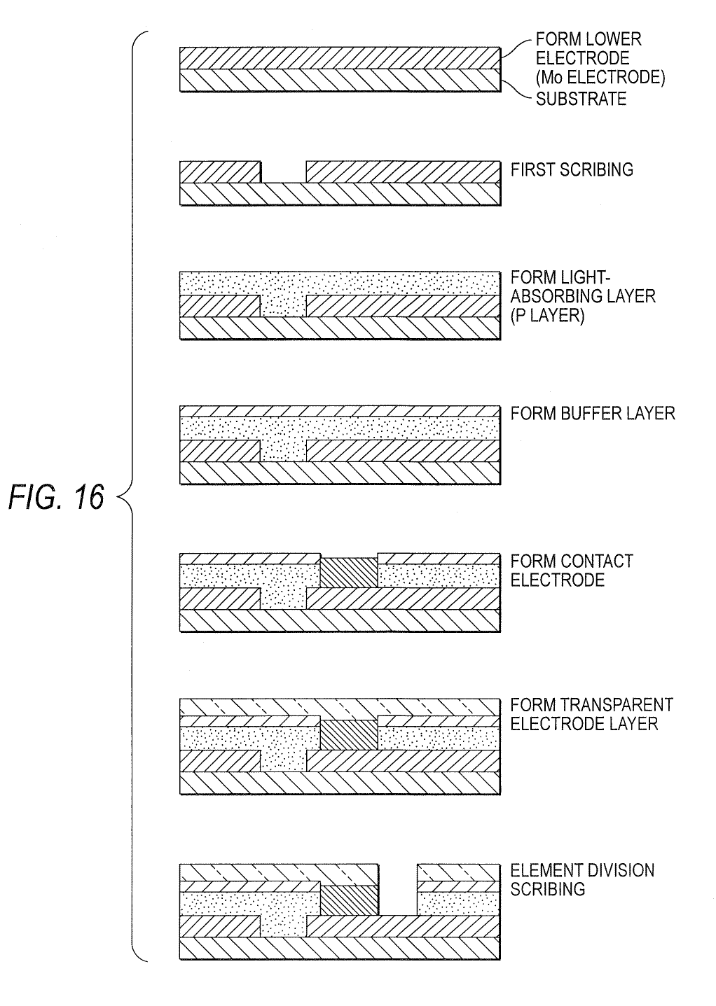

FIG. 17 is a picture of a surface of a solar cell in which a contact electrode is formed by a laser contact forming process of the invention.

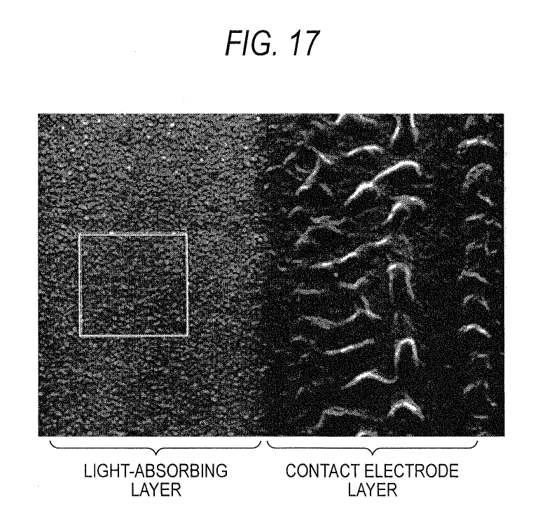

### DETAILED DESCRIPTION OF THE PREFERRED EMBODIMENTS

### Example 1

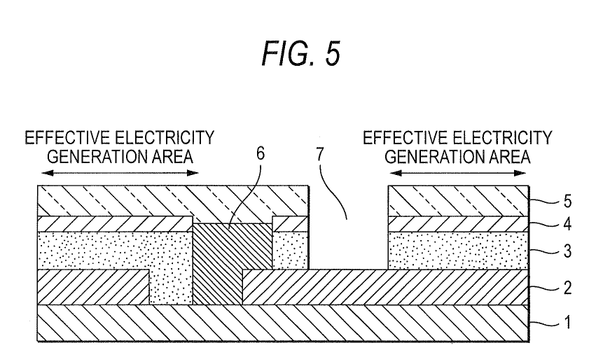

FIG. 5 is a sectional view illustrating a chalcopyrite solar cell according to the invention. The same reference numerals denote the same parts as the conventional art. In the chalcopyrite solar cell of the invention, a single unit cell (herein, referred to as “a unit cell”) is formed out of a lower electrode layer (Mo electrode layer) 2 formed on a substrate 1, a light-absorbing layer (CIGS light-absorbing layer) 3 including copper, indium, gallium, and selenium, a high-resistance buffer layer thin film 4 formed of InS, ZnS, CdS, and the like on the light-absorbing layer thin film, and an upper electrode thin film (TCO) 5 formed of ZnOAl and the like. In order to connect the unit cell, a part of a contact electrode 6 connecting the upper electrode and the lower electrode is formed to overlap with a dividing line of the lower electrode 2 formed by a first scribing. That is, the contact electrode 6 is formed between the adjacent lower electrodes 2, 2 and on one of the adjacent lower electrodes 2.

The adjacent unit cells are electrically connected to each other by connecting one upper transparent electrode layer 5 to the other lower electrode layer 2 through the contact electrode 6 as a part of the upper transparent electrode 5. A dead space 9 extending from the contact electrode 6 remains in an element dividing groove 7.

The contact electrode 6, as described below, has a Cu/In ratio higher than a Cu/In ratio of the light-absorbing layer 3, that is, has lower In. The contact electrode 6 has a p+ type or a conductive characteristic to the light-absorbing layer as a p-type semiconductor.

In the invention, the upper electrode formed by a third scribing and a diving line (scribing line) which divides the buffer layer and the light-absorbing layer are provided to be adjacent to the contact electrode. In conventional, the dead space is continuously formed in the contact electrode. However, in the invention, the light-absorbing layer is formed on a one side of the contact electrode and the groove formed by the third scribing is continuously formed on the other side.

In the embodiment, a flat glass is used as a substrate substance. However, it may be used a texture substrate having an unevenness on the surface thereof or a substrate formed of stainless, carbon, mica, polyimide, or ceramic.

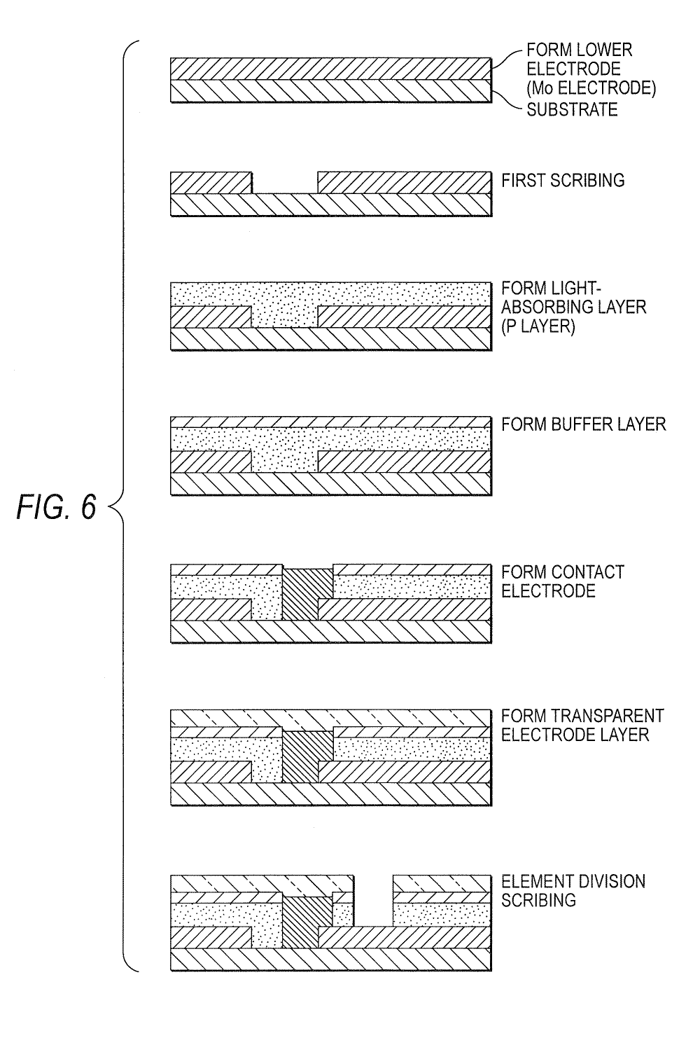

A method of manufacturing the chalcopyrite solar cell of the invention is described with reference to FIG. 6. First, a Mo (molybdenum) electrode as a lower electrode is formed on a substrate into a film by a sputtering, deposition, or the like. Titan or tungsten may be used in the lower electrode other than molybdenum. Next, the Mo electrode is removed and divided by radiating laser (first scribing).

The laser dividing the lower electrode is preferably the third harmonic of an excimer laser with a wavelength of 248 nm or an Nd YAG laser with a wave length of 355 nm. A process width is preferably in the range of 80 to 100 μm, whereby it is possible to secure insulation between the adjacent Mo electrodes.

After the first scribing, copper (Cu), indium (In), and gallium (Ga) are attached by a sputtering or deposition to form a layer call as a precursor.

The precursor is input to a forge and is annealed in atmosphere of selenium hydride (H₂Se) gas at 400° C. to 600° C., whereby a p-type light-absorbing layer is obtained. The annealing process is generally called as gaseous selenide or simply selenide.

Some methods is developed as a process of forming a light-absorbing layer, for example, a method of performing anneal after forming Cu, In, Ga, and Se by deposition. In the embodiment, the method using the gaseous selenide is described. However, In the invention, the process of forming the light-absorbing layer is not limited.

Next, an n-type buffer layer such as CdS, ZnO, and InS is laminated on the light-absorbing layer. The buffer layer is formed generally by a dry process such as sputtering or a wet process such as CBD (chemical bath deposition). The buffer layer may be omitted by improvement of the transparent upper electrode described later.

Next, by radiating the laser beam, the contact electrode is formed by reforming the light-absorbing layer. The buffer layer is formed to be very thinner than the light-absorbing layer. Accordingly, although the laser beam is radiated to the buffer layer, an influence depend on the existence of buffer layer is not shown also in accordance with the experiment by the inventors. In the invention, the laser beam is radiated to overlap with the dividing line (scribing line) of the lower electrode formed by the first scribing.

Then, a transparent electrode such as ZnOAl which becomes the upper electrode is formed on the buffer layer and the contact electrode by sputtering and the like. Finally, the buffer layer and the precursor are removed to be divided by radiating a laser or a metal needle (element division scribing, third scribing). In this case, it is preferable to secure the process width in the range of 80 to 100 μm.

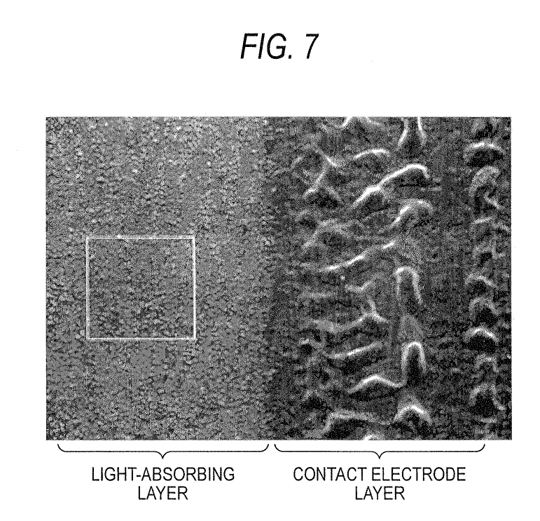

FIG. 7 is an SEM picture taken of the light-absorbing layer and the surface of the contact electrode after radiating the laser. As shown in FIG. 7, from the light-absorbing layer growing in a particle shape, it can be found that the surface of the light-absorbing layer is molten to re-crystallize the contact electrode by the energy of the laser.

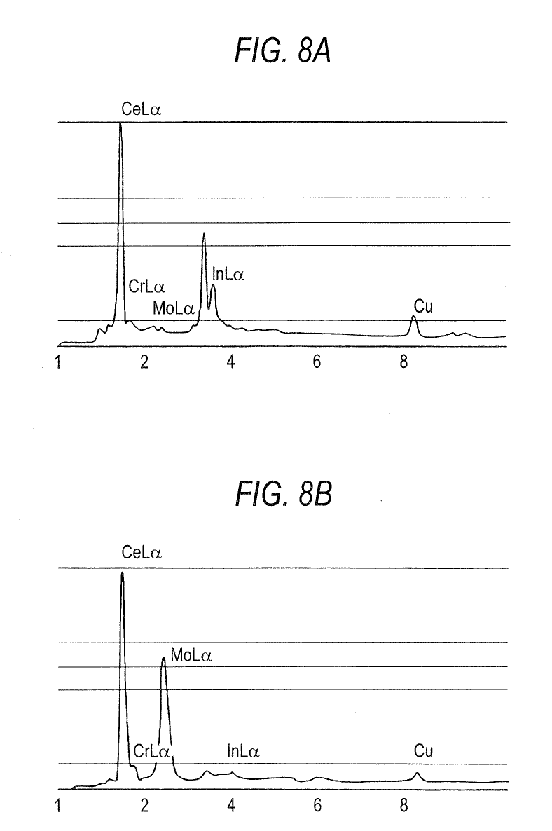

In order to specifically analysis them, the contact electrode formed according to the invention is compared with the light-absorbing layer before radiating the laser with reference to FIG. 8. FIG. 8A shows a component analysis result of the laser contact portion in which the laser contact forming process is not performed. FIG. 8B shows a component analysis result of the laser contact portion in which the laser contact forming process is performed. An EPMA (Electron Probe Micro-Analysis) is used in the analysis. In the EPMA, an accelerated electron ray is radiated an object and thus a characteristic spectrum of X-ray generated by exciting the electron ray is analyzed, whereby the constituent element is detected and the ratio (density) of the constituent element is analyzed.

From FIG. 8, it can be found that the indium (In) significantly decreases in the contact electrode relative to the light-absorbing layer. This decrease range is counted by the EPDA device. As the result, the range is 1/3.61. Similarly, the decrease range of copper (Cu) is counted. As the result, the range is 1/2.37.

As described above, by radiating the laser, it can be found that In significantly decreases and In decreases in the ratio thereof more greatly than Cu.

The other characteristic is that the molybdenum (Mo), which is not detected in the light-absorbing layer, is detected. The reason of this variation is considered. According to the simulation by the inventors, for example, when a laser beam with a wavelength 355 nm is radiated at 0.1 J/cm², the surface temperature of the light-absorbing layer rises up to 6,000° C. Of course, the temperature rises up in the inside (lower portion) of the light-absorbing layer. However, the light absorbing layer used in the embodiment has 1 μm and the inside of the light-absorbing layer may become significant high temperature.

Herein, a melting point of indium is 156° C. and a boiling point thereof is 2,595° C. A melting point of copper is 1,084° C. and a boiling point thereof is 2,595° C. Accordingly, the indium may reach the boiling point to a portion deeper than the light-absorbing layer. Since a melting point of molybdenum is 2,610° C., the molybdenum in some extent existing in the lower electrode may be molten to be taken in the light-absorbing layer.

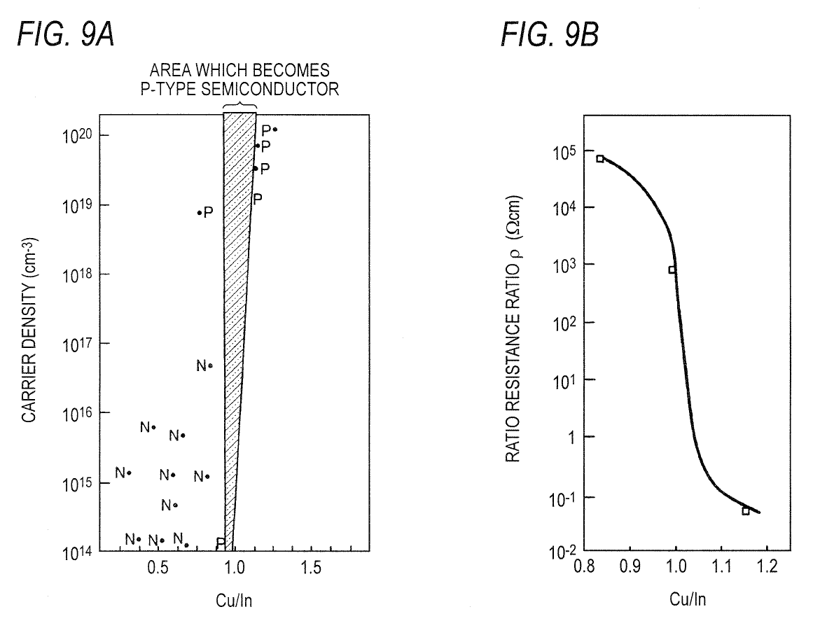

Characteristics due to a variation in the ratio of copper and indium are considered. FIG. 9 shows a variation in characteristics due to a Cu/In ratio. FIG. 9A shows differences in a carrier density of the light-absorbing layer due to a Cu/In ratio and FIG. 9B shows a variation in a resistance ratio due to a Cu/In ratio.

As shown in FIG. 9A, in order to be used as a light-absorbing layer having a property of a p-type semiconductor, it is required to control the Cu/In ratio in the range of 0.95 to 0.98. As shown in FIG. 8, in the contact electrode in which the contact electrode forming process of radiating the laser is performed, the Cu/In ratio varies from the measured value of copper and indium to a value lager than 1 in the Cu/In ratio. Accordingly, the contact electrode may vary into a p+ (plus) type or a metal. Herein, as focused in FIG. 9B, the resistance ratio rapidly decreases as the Cu/In ratio becomes larger than 1. Specifically, when the Cu/In ratio is in the range of 0.95 to 0.98, the resistance ratio rapidly decreases to 10⁴ Ωcm. Meanwhile, when the Cu/In ratio becomes 1.1, the resistance ratio rapidly decreases to about 0.1 Ωcm.

Next, the molybdenum taken in the light-absorbing is considered. The Molybdenum is an element included in group 6 of the periodic table and has a characteristic of non-resistance 5.4×10⁻⁶ Ωcm. The light-absorbing layer is molten and re-crystallized in a form of taking molybdenum, whereby the resistance ratio decreases. From the above-mentioned two reasons, it is considered that the contact electrode is deformed into a p+ (plus) type or a metal to make lower than the light-absorbing layer in resistance.

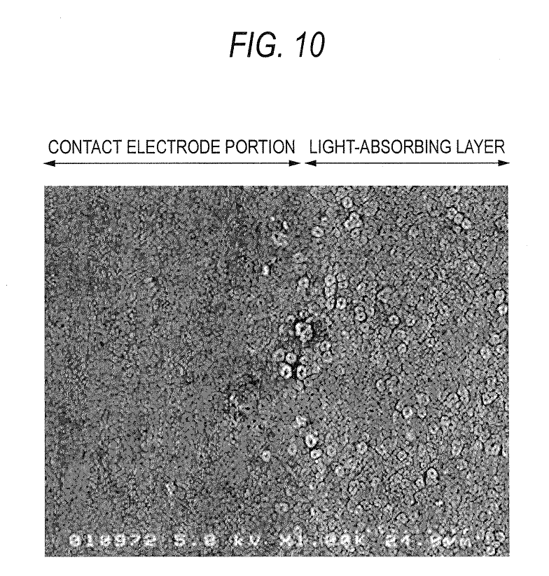

Next, the lamination of the transparent electrode layer onto the contact electrode is described. FIG. 10 is a microscope picture taking the surface of the chalcopyrite solar cell after the TCO lamination. In the conventional scribing, it is required to perform the second scribing so as to form the dead space at some distance from the scribing line formed by the first scribing. However, in the invention, since the contact electrode is formed which the light-absorbing layer is reformed so that a part thereof overlaps with the scribing line formed by the first scribing, the monolithic series connection structure can be obtained without forming the dead space. In addition, since the differential level corresponding to the film thickness of the light-absorbing layer does not exist, the transparent electrode is not damaged.

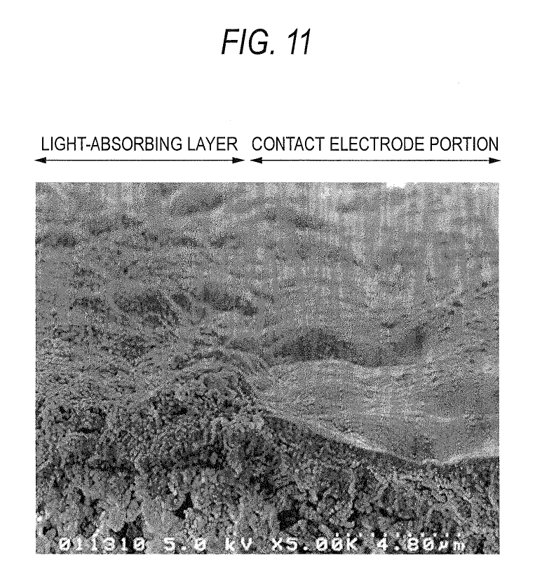

Next, in order to clear that the thickness of the contact electrode little changes in comparison with the film thickness of the light-absorbing layer, FIG. 11 shows a sectional SEM picture of the contact electrode and the light-absorbing layer. A laser with a frequency of 20 kHz, an output of 467 mW, and a pulse width of 35 ns is radiated five times to the contact electrode shown in FIG. 11. The reason that the laser is radiated five times is to confirm decrease in thickness of the contact electrode by the radiation of the laser.

As shown in FIG. 11, even when the laser is radiated five times, the thickness of the contact electrode remains in a significant extent.

In the experiment of the inventors, the generation efficiency (conversion efficiency) of the cell improved to about 10.6%. This is considered as an increase in the electricity generation area due to decrease in dead space and an increasing effect due to decrease in series resistance value.

Accordingly, a part of the contact electrode reforming the light-absorbing layer overlaps with the scribing line formed by the first scribing, whereby the electricity generation area can increase and the inner resistance value of the series connection can decrease. Consequently, the chalcopyrite solar cell having the high photoelectric conversion efficient can be obtained.

### Example 2

In the conventional scribing, it is required to perform the second scribing so as to form the dead space at some distance from the scribing line formed by the first scribing and required to perform the third scribing so as to form the dead space at some distance from the second scribing line. However, in the invention, since the contact electrode is formed which the light-absorbing layer is reformed so as to overlap a part thereof to the scribing line formed by the first scribing and the element division scribing (third scribing line) is formed so as to overlap a part thereof to the contact electrode, the monolithic series connection structure can be obtained without forming the dead space. In addition, since the differential level corresponding to the film thickness of the light-absorbing layer does not exist, the transparent electrode is not defeated.

In the experiment of the inventors, the generation efficiency (conversion efficiency) of the cell improved to about 11.1%. This is considered as an increase in the electricity generation area due to decrease in dead space and an increasing effect due to decrease in series resistance value.

Accordingly, a part of the contact electrode reforming the light-absorbing layer overlaps with the scribing line formed by the first scribing and a part of the element division scribing line overlaps with the contact electrode, whereby the electricity generation area can increase and the inner resistance value of the series connection can decrease. Consequently, the chalcopyrite solar cell having the high photoelectric conversion efficient can be obtained.

### Example 3

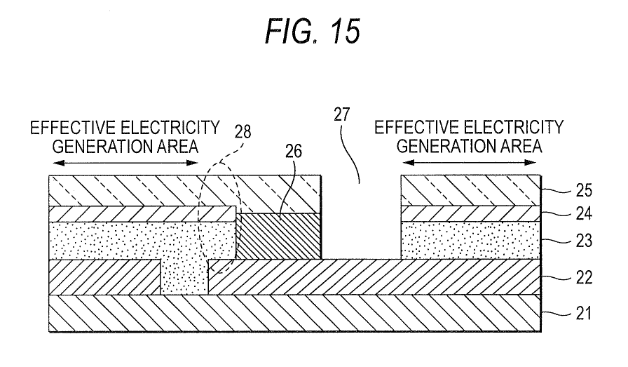

FIG. 15 is a sectional view illustrating a chalcopyrite solar cell according to the invention. The same reference numerals denote the same parts as the conventional art. In the chalcopyrite solar cell of the invention, a single unit cell (herein, referred to as “a unit cell”) is formed out of a lower electrode layer (Mo electrode layer) 22 formed on a substrate 21, a light-absorbing layer (CIGS light-absorbing layer) 23 including copper, indium, gallium, and selenium, a high-resistance buffer layer thin film 24 formed of InS, ZnS, CdS, and the like on the light-absorbing layer thin film, and an upper electrode thin film (TCO) 25 formed of ZnOAl and the like. In order to connect the unit cell, a part of a contact electrode connecting the upper electrode and the lower electrode is formed to be adjacent to a dividing line formed by a below-described element division scribing (third scribing). That is, the contact electrode 26 is formed on one lower electrode 22 separated from a space between the adjacent lower electrodes 22, 22 and on one of the adjacent lower electrodes 22.

The adjacent unit cells are electrically connected to each other by connecting the upper transparent electrode layer 25 of one unit cell to the lower electrode layer 22 of the other unit cell through the contact electrode 26. A dead space 28 extending from the contact electrode 26 remains in an element dividing groove 27 which divides the unit cell and an opposite side thereof.

In the invention, the upper electrode formed by a third scribing and a dividing line (scribing line) which divides the buffer layer and the light-absorbing layer include a part reformed by a contact electrode forming process. That is, in the past, the dead spaces 28, 29 extended to the contact electrode. However, in the invention, one side of the contact electrode is formed of the groove 27, whereby the dead space 28 remains only on the opposite side.

A transparent electrode (TCO) such as ZnOAl which becomes the upper electrode is formed on the buffer layer and the upside of the contact electrode by a sputtering and the like. Finally, the TCO, the buffer layer, and the precursor are removed by radiating a laser or a metal needle to be divided (third scribing, element division scribing). This element division scribing is performed so as to include a part of the contact electrode.

In the conventional scribing, it is necessary that the third scribing is performed so as to form the dead space separated in some extends from the scribing line formed by the second scribing. However, in the invention, since the element division scribing line (third scribing line) is formed so that a part thereof overlaps with the contact electrode formed by radiating a laser beam, a monolithic series connection structure can be obtained without the dead space. In addition, since a differential level corresponding to the film thickness of the light-absorbing layer does not exist, the transparent electrode may be not damaged. Accordingly, the series resistance value decreases.

In the experiment performed by the inventors for verifying this, by applying the invention, it is confirmed that the electricity-generation efficiency (conversion efficiency) of the cell is improved to about 10.6%. This is considered as an increase in the electricity generation area due to decrease in dead space and an increasing effect due to decrease in series resistance value as described above.

Accordingly, the electricity generation area can increase by overlapping a part of the element division scribing line to the contact electrode reforming the light-absorbing layer and the inner resistance value of the series connection can decrease. Consequently, the chalcopyrite solar cell having the high photoelectric conversion efficient can be obtained.

What is claimed is:

1. A chalcopyrite solar cell, comprising:
a substrate;
a plurality of lower electrodes formed by dividing a conductive layer formed on the substrate;
a chalcopyrite light-absorbing layer formed on the plurality of lower electrodes and divided into a plurality of parts;
a contact electrode which is formed between the adjacent lower electrodes and on one of the adjacent lower electrodes and which has a conductivity higher than that of the light-absorbing layer by reforming a part of the light-absorbing layer; and
an upper electrode which is a transparent conductive layer divided into a plurality of parts at a portion adjacent to the contact electrode.

2. The chalcopyrite solar cell according to claim 1, wherein
the contact electrode has a Cu/In ratio thereof higher than a Cu/In ratio of the light-absorbing layer.

3. The chalcopyrite solar cell according to claim 1, wherein
the contact electrode is formed of an alloy containing molybdenum.

4. The chalcopyrite solar cell according to claim 1, wherein
the upper electrode is formed on the light-absorbing layer with a buffer layer interposed therebetween.

5. A method of manufacturing a chalcopyrite solar cell comprising:
a conductive layer forming step of forming a conductive layer which becomes a lower electrode on a substrate;
a first scribing step of dividing the conductive layer into a plurality of lower electrodes;
a light-absorbing layer forming step of forming a light-absorbing layer on the surfaces of the plurality of lower electrodes and the surface of the substrate therebetween;
a contact electrode forming step of radiating a laser beam between the adjacent lower electrodes of the light-absorbing layer and onto one of the adjacent lower electrodes and reforming the light-absorbing layer so that a conductivity of the radiated part of the light-absorbing layer is higher than a conductivity of the non-radiated part thereof;
a transparent electrode forming step of laminating a transparent electrode layer; and
an element division scribing step of dividing the transparent electrode so as to include the part reformed in the contact electrode forming step.

6. The method according to claim 5, wherein
a buffer layer is formed after the light-absorbing layer forming step, and
a laser beam is radiated from the upside of the buffer layer so as to include a part divided in the first scribing step.

7. The chalcopyrite solar cell according to claim 1, further comprising:
a dead space continuously remaining in an element division groove of the contact electrode.

8. The chalcopyrite solar cell according to claim 7, wherein
the contact electrode has a Cu/In ratio thereof higher than a Cu/In ratio of the light-absorbing layer.

9. The chalcopyrite solar cell according to claim 7, wherein
the contact electrode is formed of an alloy containing molybdenum.

10. The chalcopyrite solar cell according to claim 7, wherein
the upper electrode is formed on the light-absorbing layer with a buffer layer interposed therebetween.

11. A method of manufacturing a chalcopyrite solar cell, comprising:
a conductive layer forming step of forming a conductive layer which becomes a lower electrode on a substrate;
a first scribing step of dividing the conductive layer into a plurality of lower electrodes;
a light-absorbing layer forming step of forming a light-absorbing layer on the surfaces of the plurality of lower electrodes and the surface of the substrate therebetween;
a contact electrode forming step of radiating a laser beam between the adjacent lower electrodes of the light-absorbing layer and onto one of the adjacent lower electrodes so as not to overlap with a part to which an element division scribing is performed later and reforming the light-absorbing layer so that a conductivity of the radiated part of the light-absorbing layer is higher than a conductivity of the non-radiated part thereof;
a transparent electrode forming step of laminating a transparent electrode layer; and
an element division scribing step of dividing the transparent electrode so as to include the part reformed in the contact electrode forming step.

12. The method according to claim 11, wherein
a buffer layer is formed after the light-absorbing layer forming step and a laser beam is radiated from the upside of the buffer layer so as to include a part divided in the first scribing step.

13. A chalcopyrite solar cell, comprising:
a substrate;
a plurality of lower electrodes formed by dividing a conductive layer formed on the substrate;
a chalcopyrite light-absorbing layer formed on the plurality of lower electrodes and divided into a plurality of parts;
a contact electrode which is formed on one lower electrode separated from the space between the adjacent lower electrodes and which has a conductivity higher than that of the light-absorbing layer by reforming a part of the light-absorbing layer; and
an upper electrode which is a transparent conductive layer divided into a plurality of parts at a portion adjacent to the contact electrode.

14. The chalcopyrite solar cell according to claim 13, wherein
the contact electrode has a Cu/In ratio higher than a Cu/In ratio of the light-absorbing layer.

15. The chalcopyrite solar cell according to claim 13, wherein
the contact electrode is formed of an alloy containing molybdenum.

16. The chalcopyrite solar cell according to claim 13, wherein
the upper electrode is formed on the light-absorbing layer with a buffer layer interposed therebetween.

17. A method of manufacturing a chalcopyrite solar cell comprising:
a conductive layer forming step of forming a conductive layer which becomes a lower electrode on a substrate;
a first scribing step of dividing the conductive layer into a plurality of lower electrodes;
a light-absorbing layer forming step of forming a light-absorbing layer on the surfaces of the plurality of lower electrodes and the surface of the substrate therebetween;
a contact electrode forming step of radiating a laser beam onto a part of the light-absorbing layer formed on one lower electrode separated from the space between the adjacent lower electrodes and reforming the light-absorbing layer so that a conductivity of the radiated part of the light-absorbing layer is higher than a conductivity of the non-radiated part thereof;
a transparent electrode forming step of laminating a transparent electrode layer; and
an element division scribing step of dividing the transparent electrode so as to include the part reformed in the contact electrode forming step.

18. The method according to claim 17, wherein
a buffer layer is formed after the light-absorbing layer forming step, and
a laser beam is radiated from the upside of the buffer layer so as to include a part divided in the first scribing step.
